(19) United States
(12) Patent Application Publication
(10) Pub. No.: US 2024/0201258 A1
(43) Pub. Date: Jun. 20, 2024

(54) METHOD AND DEVICE FOR MONITORING THE STATE OF HEALTH OF A CONTACTOR

(71) Applicant: WEBASTO SE, Stockdorf (DE)

(72) Inventors: Patrick ASSMANN, Stockdorf (DE); Michael ZEILBECK, Stockdorf (DE); Andreas HEIZER, Stockdorf (DE); Marc HARTMEYER, Stockdorf (DE); Pirmin STUTZ, Stockdorf (DE)

(21) Appl. No.: 17/909,946

(22) PCT Filed: Mar. 12, 2021
(86) PCT No.: PCT/EP2021/056336

§ 371 Date: Sep. 7, 2022

(30) Foreign Application Priority Data
Mar. 12, 2020 (DE) 10 2020 106 856.5

(51) Int. Cl. G01R 31/327; G01R 19/10; G01R 19/165; H01M 10/42; H01M 10/48; H02H 7/18

(52) U.S. Cl. CPC G01R 31/327; G01R 19/10; G01R 19/16576; H01M 10/425; H01M 10/488; H02H 7/18

(57) ABSTRACT

A method for monitoring the state of health of at least one contactor in a battery pack, wherein the battery pack comprises at least one battery cell, a first interface line and a second interface line, wherein at least one switchable first contactor is arranged in the first interface line between the interface and the at least one battery cell, and at least one switchable second contactor is arranged in the second interface line between the interface and the at least one battery cell, comprising steps for the measurement of a first differential voltage across the open first contactor and/or the measurement of a second differential voltage across the open second contactor, and the monitoring of the state of health of the first contactor on the basis of the measured first differential voltage and/or determination of the state of health of the second contactor on the basis of the measured second differential voltage.

### CROSS REFERENCE TO RELATED APPLICATIONS

This application is a national stage of International Application No. PCT/EP2021/056336 filed Mar. 12, 2021, which claims priority from German Patent Application No. DE 10 2020 106 856.5 filed Mar. 12, 2020 in the German Patent and Trademark Office, the disclosures of which are incorporated herein by reference in their entirety.

### BACKGROUND

### Technical Field

The present invention relates to a method for monitoring the state of health of at least one contactor in a battery pack. The invention further relates to a battery control system for employment in a battery pack, and to a battery pack.

### Related Art

In vehicles which are driven by electric motors, battery systems are employed, which deliver energy to the drive system. These battery systems are frequently comprised of a plurality of battery packs which, in turn, are comprised of a plurality of battery modules, each of which, in turn, accommodates a plurality of battery cells.

In order to ensure the operational security of battery packs, it is intended that these should be of an inherently safe design and, in consequence, can be switched to a de-energized state vis-à-vis the exterior by means of integrated contactors. Contactors incorporated in battery packs therefore assume a key function, such that it is necessary for the functionality thereof to be monitored.

A method for the diagnosis of wear-related contactor ageing is known from DE 10 2012 215 190 A1. Insulation resistance, i.e. the electrical resistance of an open contactor, declines over the service life of a contactor. Measurement of the insulation resistance of the contactor, in relation to voltage and current, thus permits conclusions to be drawn with respect to the state of health thereof. Immediately the insulation resistance falls below a limiting value, measures are implemented in accordance with the disclosure of DE 10 2012 215 190 A1.

DE 10 2012 209 138 A1 discloses a method for determining the state of health of a fuse. According to this method, a current flowing in a fuse is measured and logged, in order to permit the continuous determination of the state of health of the fuse.

DE 10 2014 200 265 A1 discloses a battery system having a high-voltage battery and a protection circuit, the functional state of which is monitored. Specifically, an up-circuit protection circuit is assigned to a contactor for this purpose. This circuit comprises two parallel-connected circuit branches, in each of which a fuse and a current sensor are arranged. Evaluation of the respective current values flowing in the protection circuit permits a diagnosis of the functional state of the protection circuit.

DE 10 2015 006 206 A1 discloses a high-voltage system having a switching contactor. Specifically, the risk of contactor jamming is identified, i.e. the jamming of a switchable contactor such that it is no longer switchable. As an approach to a solution for the prevention of the problematic effects of contactor jamming, it is proposed that the switching contactor be connected in series with a further switching element. In this manner, redundancy in the high-voltage system is achieved, thereby reducing dependence upon a single switching contactor.

### SUMMARY

An improved method for monitoring the state of health of at least one contactor in a battery pack, together with a battery control system and a battery pack are described herein according to various embodiments.

Correspondingly, a method is proposed for monitoring the state of at least one contactor in a battery pack.

A contactor can be an electromechanical isolating element in an electric circuit, such as, for example, a relay.

A state of health can refer to a condition of the contactor which is evidential of the properties thereof. In particular, this can be understood as the isolating capability of the corresponding contactor, i.e. the capability thereof for the electrical isolation, for example of a battery pack, from the remainder of the battery system. One parameter which is indicative of isolating capability is the insulation resistance of the contactor. Insulation resistance can be understood as a resistance which is constituted across an open contactor.

The corresponding value of insulation resistance can be essentially dependent upon an air gap between contactor contacts in an interrupter chamber of a contactor. An intact and unused contactor can assume an insulation resistance of the order of several gigaohms.

Over the course of its service life, however, the insulation resistance can decline, which can be described as the ageing of the contactor. This decline in the insulation resistance of the contactor can be caused, for example, by contamination, wear and/or arc erosion on the contactor contacts, which can correspondingly result in a decrease in the insulation resistance. Further factors which can result in a reduction in the insulation resistance of the contactor include contamination, dust and particles which are present in the contactor housing, and which are conductive to the formation of bridges or conduction paths between the contactor contacts. Moreover, purely mechanical factors can also result in a reduction of the insulation resistance, such as, for example, restrictions in the mobility of the contactor contacts relative to one another, as a result of which the contactor contacts, in the open state, are not sufficiently spaced from one another, in a manner which is likewise conductive to the formation of bridges or conduction paths.

At least the above-mentioned factors play a role in the consideration of the insulation resistance of the contactor and, in the first instance, are considered here as a whole, on the grounds that, for the operation of a contactor in a battery system, the only relevant factor is whether the contactor is capable of executing the regulation isolation of battery cells from loads.

This decline in insulation resistance can also be described as the ageing of the contactor, wherein ageing—as described above—can be attributed to mechanical, chemical and electrical causes. Depending upon the frequency of switching operations for the interruption of currents, together with the magnitude and direction of the respective currents switched, contactor ageing will proceed more rapidly or more slowly.

Below a specific insulation resistance, for example below 300 kiloohms, secure isolation of the battery pack from the remainder of the battery system under all load conditions, particularly in the event of high currents, and the requisite safety shutdown, can no longer be reliably achieved on the grounds that, for example, the generation of an arc between the switching contacts results in the unintentional further conduction of the current flux which it is intended to interrupt.

A battery pack comprises at least one battery cell for the electrochemical storage of electrical energy as well as a first interface line and a second interface line for the delivery of electrical energy to an interface.

The interface can be configured, for example, in the form of a high-voltage socket-outlet, such that the battery pack can be electrically connected to a battery system by means of a simple plug-in connection. In a vehicle, connection of the battery pack to the battery system can be executed, for example, via a “vehicle interface box” (VIB), in which further battery packs are interconnected to form a logically constructed vehicle battery, for example for the formation of a high-voltage system for the operation of a vehicle which is driven by an electric motor.

A battery pack can comprise a plurality of battery modules. The respective battery modules, in turn, can accommodate individual electrochemical battery cells, which undertake the actual storage of electrical energy.

In the first interface line, at least one switchable first contactor is arranged between the interface and the at least one battery cell and, in the second interface line, at least one switchable second contactor is arranged between the interface and the least one battery cell. By this arrangement of the first contactor and the second contactor between the interface and the battery cell, secure isolation of the battery cell from the interface is permitted, thereby resulting in the enhancement of safety standards and controllability.

The method according to the invention comprises the following steps: measurement of a first differential voltage across the open first contactor. The first differential voltage can be a voltage which is present in the battery pack, which is at least measured, inter alia, across the open first contactor.

Alternatively or additionally, a second differential voltage is measured across the open second contactor. In an analogous manner to the first differential voltage, the second differential voltage can also be a voltage which is present in the battery pack, and which is at least measured, inter alia, across the open second contactor.

The method according to the invention moreover comprises a step for monitoring the state of health of the first contactor on the basis of the measured first differential voltage. As the first differential voltage is at least partially measured across the open first contactor, it permits a monitoring of the state of health of the first contactor, as the first differential voltage changes in response to the ageing of the contactor and thus, additionally, in response to the variation in insulation resistance associated with the ageing of the contactor.

However, it should be observed that, in the proposed method, the internal resistance of the contactor is not explicitly determined. In particular, no current measurement is executed in addition to voltage measurement, such that the internal resistance, in the absence of current measurement, cannot be calculated from the differential voltage. The method is exclusively based upon the measurement of the differential voltage.

By the process step for “monitoring”, it can be understood that, on the basis of the “first differential voltage” as an input variable, an output variable is generated, which delivers information on the state of health of the first contactor to a further system component, such as a further control device, a display unit or a user. In its simplest form, this can exclusively be information as to whether the measured differential voltage exceeds a specified value or lies below a specified value.

Alternatively or additionally, the state of health of the second contactor is monitored on the basis of the measured second differential voltage. As the second differential voltage is at least partially measured via the open second contactor, in an analogous manner to the first contactor, this permits a monitoring of the state of health of the second contactor. The effects of the method upon one contactor are thus likewise applicable to the other contactor. In other words, the method thus permits, on the exclusive basis of the measurement of at least one differential voltage, the monitoring of the ageing process in at least one contactor.

Thus, according to the proposed method, a voltage drop across an open contactor is measured. In this manner, both the electrical and the mechanical functionality of a contactor are monitored.

The proposed method permits, in consideration of a simple voltage measurement, a conclusion to be drawn with respect to the state of health of the first contactor and/or of the second contactor.

Conversely, resistance measurements requiring the determination of a current flux, which varies substantially between the two operating states “contactor open” and “contactor closed”, are correspondingly disregarded, as a result of which the method can be executed with no additional current measurements.

The accuracy of the proposed method permits on the one hand a high degree of operational security, as the state of health of a contactor, and thus the presence of a secure operating state, can be reliably monitored, and the method permits on the other hand an accurate adjustment of maintenance cycles, as a contactor can be employed up to its EOL (end of life), and does not need to be decommissioned upon the completion of a predefined number of switching cycles.

The method can advantageously comprise at least one of the following further steps: monitoring of the state of health of the first contactor on the basis of a comparison of the measured first differential voltage with a first voltage threshold value and/or determination of the state of health of the second contactor on the basis of a comparison of the measured second differential voltage with a second voltage threshold value.

The first voltage threshold value and the second voltage threshold value can be preset, or can be dynamically adjusted over the service life of a circuit. They can assume mutually identical or differing values. By means of a corresponding comparison with a voltage threshold value, the method can be executed in a robust manner, without a high degree of computing effort.

According to the method, advantageously, the at least one differential voltage can be measured in consideration of at least one reference potential wherein, in one embodiment, at least one crossover voltage is measured via the respective open contactor. The reference potential is a voltage which differs from the differential voltage, which is present in the battery pack. It can vary according to the state of charge and the state of health of the battery pack or the battery cells.

A crossover voltage can, for example, be a voltage drop across a contactor, for example an open contactor, and a further component in the circuit.

A crossover voltage can moreover be a measured variable which is logged in any event by a battery control system. It is thus possible for the measured crossover voltage to be considered, firstly with respect to contactor ageing, and secondly for the monitoring of other characteristic variables in the battery pack. This improves the efficiency of processes executed in the battery pack, and the responsiveness of the battery pack.

According to the method, advantageously, differential voltages on the first contactor and the second contactor can be respectively measured vis-à-vis an interface node point which faces the interface, and vis-à-vis a battery cell node point which faces the battery cell, wherein the first differential voltage is a first crossover voltage, which is present between the interface node point of the first contactor and the battery cell node point of the second contactor, and/or the second differential voltage is a second crossover voltage, which is present between the interface node point of the second contactor and the battery cell node point of the first contactor. The respective crossover voltage can thus be present on two mutually electrically separate points in the battery pack circuit.

The first and second contactors can interrupt the respective electrical lines. The interface node point can be understood as a node point in the circuit which is arranged between the interface and the respective contactor. The battery cell node point can correspondingly be understood as a node point in the circuit which is arranged between the respective contactor and the at least one battery cell. The respective node points can correspond to the closing contacts or connection terminals of the contactor. Alternatively, they can be provided at any arbitrary point between the contactor and the interface or the at least one battery cell.

The method can advantageously comprise at least one of the following steps: generating a warning signal in the event that the first crossover voltage achieves or exceeds a warning voltage threshold value and/or generating a warning signal in the event that the second crossover voltage achieves or exceeds a second warning voltage threshold value. A warning signal can be transmitted by a battery control device to a further control device, a display unit or a user, in order to indicate that the state of health of the first or second contactor is critical. As a warning signal is generated before any switching of the respective contactor is suppressed, replacement of the contactor with no enforced outage of the battery pack is permitted. Maximum operational security and optimum exploitation are combined accordingly.

The method can advantageously comprise at least one of the following steps: suppressing the switching of the first contactor in the event that the first crossover voltage exceeds a first voltage threshold value, and/or suppressing the switching of the second contactor in the event that the second crossover voltage exceeds a second voltage threshold value, and/or suppressing the switching of the first contactor and the second contactor in the event that the first crossover voltage exceeds the first voltage threshold value or the second crossover voltage exceeds the second voltage threshold value.

Both the warning voltage threshold value and the voltage threshold value can be established in volts, and are freely selectable. Manufacturer data with respect to contactor ageing, on the one hand, and a requisite safety margin, on the other, can be considered. As soon as the switching of a contactor is suppressed it can no longer be closed despite a corresponding command to ensure a disconnection from the at least one battery cell and the interface. If identical components are used for the first contactor and the second contactor, it is advantageous to specify identical values for the first voltage threshold value and the second voltage threshold value.

The warning voltage threshold value can constitute a percentage of the voltage threshold value. For example, a warning can be triggered if the respectively considered crossover voltage is 80% of the voltage threshold value. The warning voltage threshold value is thus 80% of the voltage threshold value. The margin between the warning voltage threshold value and the voltage threshold value can take account of regular user behavior and, in the event of application in a vehicle, for example, permits the vehicle user to schedule an appointment with their service workshop, and the vehicle to continue to operate regularly without a safety shutdown during normal use until then. In other words, the warning voltage value is set such that the vehicle can be operated safely throughout during regular driving and the service intervals can also be observed.

The method can advantageously comprise at least one of the following steps: determining a first reference potential between the battery cell node point of the first contactor and the battery cell node of the second contactor, and/or determining a second reference potential between the interface node point of the first contactor and the interface node point of the second contactor, wherein the first voltage threshold value is in some embodiments determined in accordance with the first reference potential and the second voltage threshold value is in various embodiments determined in accordance with the second reference potential. The respective reference potential is appropriate to the consideration of the condition, for example the state of charge, of the battery pack. By the establishment of a relationship between the reference potential and the voltage threshold value, dynamic adjustment of the voltage threshold value is permitted. This improves the flexibility and adaptability of the method.

The method can advantageously comprise the following steps: determining the state of health of the first contactor and/or of the second contactor, prior to any switching process for the closing of the respective contactor. On the basis of measuring a differential voltage for the monitoring of the state of health, a corresponding conclusion on the state of health is permitted, with no increased effort, prior to each switching operation of the respective contactor. This permits the reliable monitoring of state of health at any time, and thus further improves safety.

Advantageously, the method can also execute a step for the continuous measurement of the first differential voltage and/or of the second differential voltage. By continuous measurement, it is understood that, at each processor time interval in a control device, a corresponding differential voltage is measured. In consequence, variations, including abrupt variations in the state of health of the respective contactor are detected directly. This impacts positively upon the dynamics of monitoring.

The proposed battery control system for employment in a battery pack is appropriate to the execution of the method according to the invention.

To this end, corresponding signal lines are provided, and corresponding functionalities are structurally implemented. The battery control system can be an electronic module, which comprises a processor in which various input signals are converted into output signal. A potential input signal is a statement on the state of health of the contactor, and the respective differential voltages comprise a potential output signal.

The proposed battery pack for the supply of electrical energy to an electric drive unit comprises the following components: at least one battery cell, a first interface line and a second interface line for the delivery of electrical energy to an interface, at least one switchable first contactor, which is arranged in the first interface line, and at least one switchable second contactor, which is arranged in the second interface line. The battery pack further comprises an above-mentioned battery control system. The corresponding components of the battery pack have already been addressed in conjunction with the above-mentioned method. Corresponding features, which have been disclosed with reference to the method, are also applicable to the battery pack.

The above-mentioned object is also fulfilled by a non-volatile computer-readable storage medium, on which machine-executable instructions for the execution of the above-mentioned method are saved.

### BRIEF DESCRIPTION OF THE FIGURES

Further embodiments of the invention are described in greater detail with reference to the following description of the figures.

FIG. 1 shows a schematic view of a circuit having a first contactor and a second contactor;

FIG. 2 shows a simplified schematic view for the representation of a first crossover voltage and a second crossover voltage;

FIG. 3 shows a further schematic view of a circuit having the first contactor and the second contactor;

FIG. 4 shows an equivalent circuit diagram of a circuit having the first contactor and the second contactor;

FIG. 5 shows a first diagram of a simulated crossover voltage, plotted against the insulation resistance of the first contactor;

FIG. 6 shows a second diagram of a simulated crossover voltage, plotted against the insulation resistance of the second contactor; and

FIG. 7 shows a third diagram of a simulated set of crossover voltages, plotted against the insulation resistance.

### DETAILED DESCRIPTION

Exemplary embodiments are described hereinafter with reference to the figures. Identical, similar, or identically functioning elements in the various figures are identified by the same reference symbols, and any repeated description of these elements is omitted, in places, in the interests of avoiding redundancy.

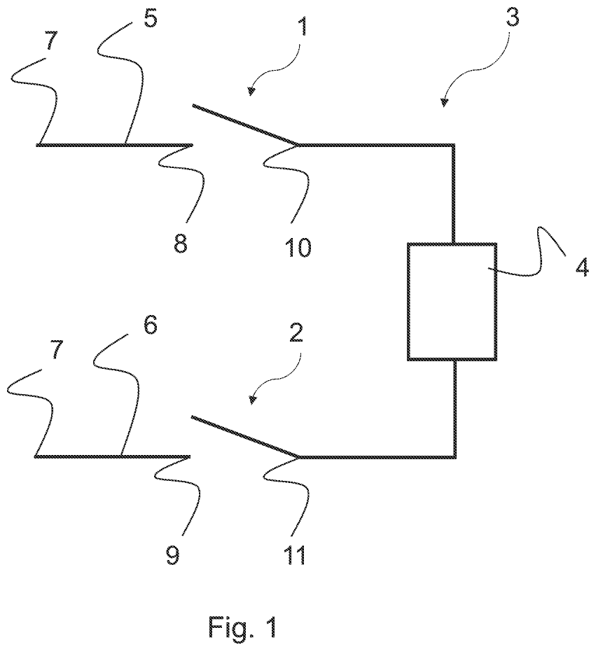

FIG. 1 shows a schematic representation of a battery pack 3, comprising at least one schematically illustrated battery cell 4 for the electrochemical storage of electrical energy. A battery pack 3 of this type can be provided, for example, in a vehicle, for the delivery of drive energy.

A plurality of battery cells 4 provided in the battery pack 3 can be structured in the form of a battery module, wherein a plurality of battery modules can also be provided in a battery packs. A plurality of battery packs 3, in turn, can be interconnected in a battery system, which can ultimately be provided for the delivery of drive energy. The battery system can be, for example, a “high-voltage system”, which operates at a rated voltage of 400V or 800V.

The battery pack 3 comprises a first interface line 5 and a second interface line 6. The first interface line 5 and the second interface line 6 deliver electrical energy to an interface 7. The interface 7 can be provided, for example, in the form of a high-voltage socket-outlet, which permits a simple electrical plug-in connection to the battery system. In other words, the battery pack 3 can be connected at the interface 7 to the remainder of the battery system, wherein electrical energy is transferred exclusively via a single plug-in connection from the battery pack 3 to the remainder of the battery system—regardless of the internal structure of the battery pack 3 and, in particular, regardless of whether one or more battery modules are arranged in the battery pack 3, or whether the battery cells 4 in the battery pack 3 are structured in a different manner. Correspondingly, in principle, the battery system considers the battery pack 3 as a single battery.

The interface 7 for the connection of the battery pack 3 can also be configured on a vehicle interface Box (VIB) such that, in this manner, the battery pack 3 can be employed, for example, for the configuration of an (unrepresented) high-voltage system, for example for the propulsion of a drive unit of a vehicle.

In the battery pack 3 according to FIG. 1, a circuit having a first contactor 1 and a second contactor 2 is represented. The first contactor 1 is arranged in the first interface line 5, and the second contactor 2 is arranged in the second interface line 6. The function of the first contactor 1 and the second contactor 2 is the isolation of the battery cells 4 from the interface 7, such that the interface 7, with the contactors 1, 2 in the open state, is not connected to the battery cells 4, and is therefore voltage-free. Correspondingly, the function of the contactors 1, 2 is the connection and disconnection of the battery pack 3. By means of the contactors 1, 2, a safety shutdown of the battery pack 3 can also be executed, in the event that the battery pack 3 or the entire battery system assumes an unstable or critical state.

In the exemplary embodiment represented, the first contactor 1 is arranged between an interface node point 8, facing the interface 7, and a battery cell node point 10, facing the battery cell 4. The first contactor 1 can thus interrupt or establish an electrical connection between the interface node point 8 and the battery cell node point 10.

In the same way, the second contactor 2 is arranged between an interface node point 9, facing the interface 7, and a battery cell node point 11, facing the battery cell 4. The second contactor 2 can thus interrupt or establish an electrical connection between the interface node point 9 and the battery cell node point 10.

FIG. 1 represents both the first contactor 1 and the second contactor 2 in the open position. In this position, the respective contactors 1, 2 deliver their respective insulation resistances.

It should be noted that the representation according to FIG. 1 is intended to illustrate the operation of the method according to this exemplary embodiment. Thus, neither the number of contactors, nor the number of battery cells, nor the number of interface lines is of a restrictive nature.

Customarily, the insulation resistances of the contactors 1, 2 are in excess of 300 megaohms. In the course of various switching cycles, however, contactors become worn, for example as a result of contact wear, arc erosion or fusion at the contacts, in the event that, during switching, a residual current has flowed and an arc has been generated accordingly. As a result of this wear, the insulation resistance of contactors can be reduced, such that the latter, upon the achievement of a predefined insulation resistance, can no longer be employed, on the grounds that isolation of the battery cells 4 from the interface 7 can no longer be ensured. This insulation resistance can be, for example, 300 kiloohms. Once this insulation resistance has been achieved, the respective contactor has reached its end of life, and will need to be replaced.

In ideal operation, contactors are switched to a de-energized state only, such that contactor ageing is essentially caused exclusively by mechanical wear. This ageing might be monitored by the metering of switching cycles. However, in the event of unforeseen operating states or the non-optimum configuration of control, it is possible that switching will be executed even where currents are flowing. Depending upon the frequency of the switching operations for the interruption of currents together with the magnitude and direction of the respective currents switched, contactor ageing will proceed more rapidly or more slowly.

It is therefore necessary for contactor ageing to be monitored more accurately, in order to prevent the continued use in a battery pack 3 of a contactor which is no longer safe. Conversely, for the conservation of resources, it is intended to prevent the premature replacement of a contactor.

According to the exemplary embodiment represented here, a first differential voltage Udif, 1 across the open first contactor 1 and/or a second differential voltage Udif, 2 across the open second contactor 2 are measured accordingly. By reference to the first measured differential voltage Udif, 1 or the measured second differential voltage Udif, 2, it is possible to determine a state of health of the first contactor 1 or of the second contactor 2, or at least to establish whether the respective contactor can still be operated in a safe manner.

A differential voltage can be understood, in the first instance, as a measured voltage which is present between two points.

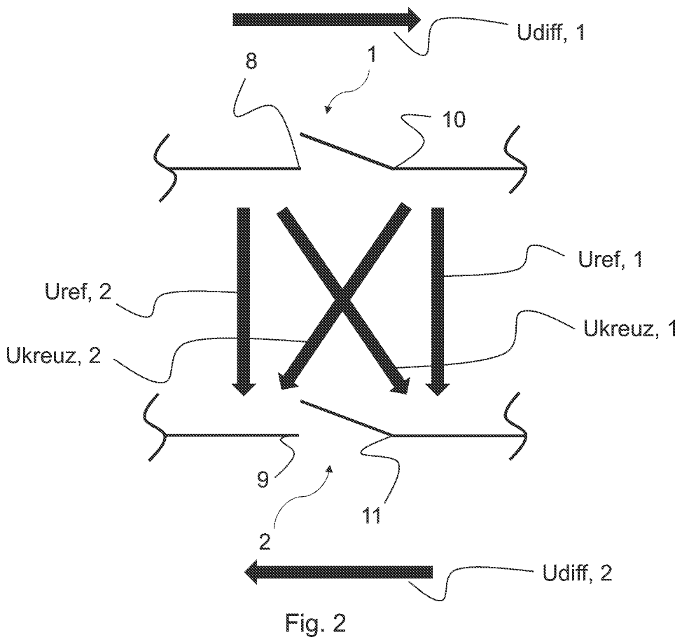

FIG. 2 illustrates specific differential voltages. Thus, as a first differential voltage Udif, 1, a first crossover voltage Ukreuz, 1 is measured. As a second differential voltage Udif, 2, a second crossover voltage Ukreuz, 2 is measured. The first crossover voltage Ukreuz, 1 is present between the interface node point 8 of the first contactor 1 and the battery cell node point 11 of the second contactor 2. The second crossover voltage Ukreuz, 2 is present between the battery cell node point 10 of the first contactor 1 and the interface node point 9 of the second contactor 2. The crossover voltages Ukreuz, 1, 2 thus permit a conclusion to be drawn with respect to a voltage drop on the first contactor 1 or on the second contactor 2—in each case in relation to a fixed reference value, i.e. with reference to the battery node point 11 and the interface node point 9 respectively of the second contactor 2. The second interface line 6 is customarily at ground potential such that, in this case, the respective reference potential is ground.

In addition to the crossover voltages Ukreuz, 1, 2, in the circuit according to FIG. 2, a first reference voltage Uref, 1 and a second reference voltage Uref, 2 are also measured. The first reference voltage Uref, 1 is present between the battery cell node point 10 of the first contactor 1 and the battery cell node point 11 of the second contactor 2, and thus corresponds to the voltage of the battery cells 4.

The second reference voltage Uref, 2 is present between the interface node point 8 of the first contactor 1 and the interface node point 9 of the second contactor 2 and thus corresponds to the voltage applied at the interface 7. By reference to the first reference voltage Uref, 1, standardization of the first crossover voltage Ukreuz, 1 is possible. By reference to the second reference voltage Uref, 2, standardization of the second crossover voltage Ukreuz, 2 is possible.

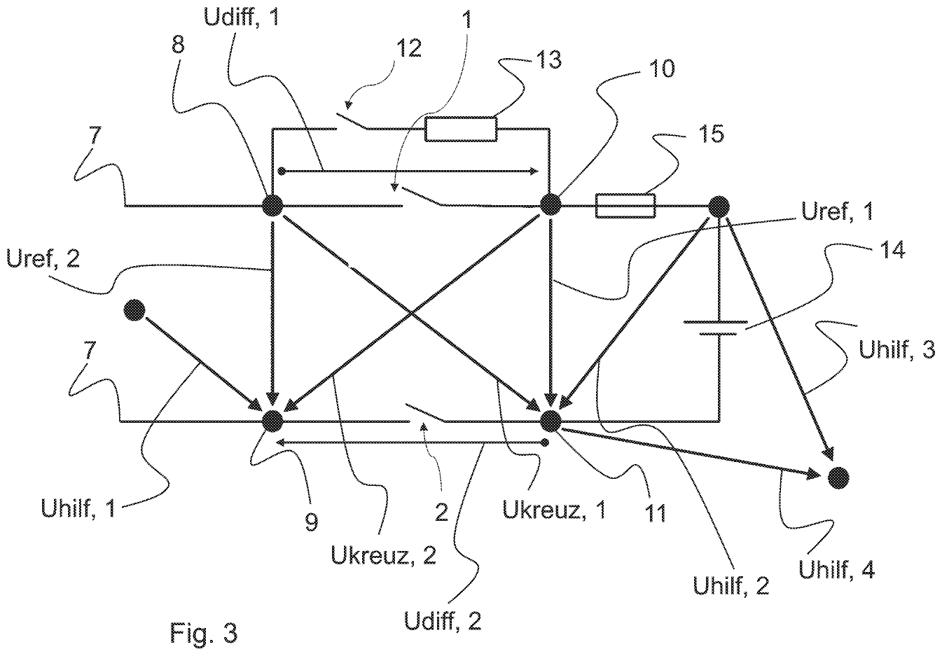

FIG. 3 shows a further representation of the circuit of a battery pack 3. This battery pack also comprises an interface 7 which permits, for example, connection to a high-voltage system.

In addition to the first contactor 1 and the second contactor 2, an auxiliary contactor 12 is provided in the circuit. An auxiliary resistor 13 is connected up-circuit of the auxiliary contactor 12. The auxiliary contactor 12 and the auxiliary resistor 13 are connected to the interface node point 8 of the first contactor 1 and the battery pack node point 10 of the first contactor 1. The function of the auxiliary contactor 12 and the auxiliary resistor 13, upon the connection of the battery pack 3 to the battery system, is to permit the pre-charging of capacitances which are present in the battery system via the auxiliary resistor 13 such that, upon the connection of the battery pack 3 to the battery system, there is no abrupt flow of excessively high currents which might result in the high loading of battery cells 4 and which, upon the closing of the contactors 1, 2, might result in the high loading and wear of the contactors 1, 2. Such protection circuits of this type are in principle well-known.

The basic mode of operation of the voltage-based monitoring of a state of health of the first contactor 1 or the second contactor 2 remains unaffected by the auxiliary contactor 12 and the auxiliary resistor 13.

The various arrows in FIG. 3 represent the various measured voltages. The first crossover voltage Ukreuz, 1, the second crossover voltage Ukreuz, 2, the first reference voltage Uref, 1 and the second reference voltage Uref, 2 are known from FIG. 2.

Moreover, in the circuit according to FIG. 3, various auxiliary voltages are measured: A first auxiliary voltage Uhilf, 1 is present between the interface node point 9 of the second contactor 2 and a grounding point. A second auxiliary voltage Uhilf, 2 is applied between a point up-circuit of a battery resistor 15 and the battery cell node point 11 of the second contactor 2. A third auxiliary voltage Uhilf, 3 is applied between the point up-circuit of the battery resistor 15 and a further grounding point. A fourth auxiliary voltage Uhilf, 4 is applied between the battery cell node point 11 of the second contactor 2 and the further grounding point.

The various auxiliary voltages are used to provide a battery control system with a detailed image of voltage conditions in the circuit according to FIG. 3. The battery resistor 15 is only indicated schematically for the representation of the resistance in the battery pack 3. For illustrative purposes only, FIG. 3 shows a DC current source 14 as the battery cell.

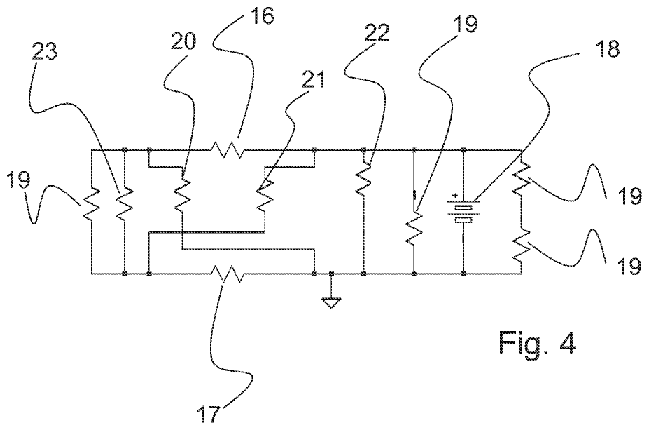

FIG. 4 represents a further circuit. The circuit according to FIG. 4 represents an equivalent circuit diagram of a battery pack 3, including measuring assemblies.

The internal resistance of the first contactor 1 together with the internal resistance of the second auxiliary contactor 12 and the protective resistor 13 are assignable to a first common internal resistance 16. The second contactor 2 is assignable to a second internal resistance 17. The DC current source 14 or the at least one battery cell 4 are assignable to a replacement battery 18. Various resistors 19 are indicated in the circuit, the function of which will not be addressed in detail here, but which are solely intended to represent conditions within the battery cells.

A measuring shunt 20 is used to determine the voltage drop in accordance with the first crossover voltage Ukreuz, 1. A measuring shunt 21 is used to determine the voltage drop in accordance with the second crossover voltage Ukreuz, 2. A further measuring shunt 22 is used to determine the voltage drop in accordance with a first reference voltage Uref, 1. A further measuring shunt 23 is used to determine the voltage drop, in accordance with a second reference voltage Uref, 2. By reference to voltage drops on the measuring shunts 20, 21, it is thus possible to determine the respective crossover voltage. This permits an efficient monitoring or determination of ageing processes in the respective contactors 1, 2, or of the internal resistances 16, 17 which are assigned thereto.

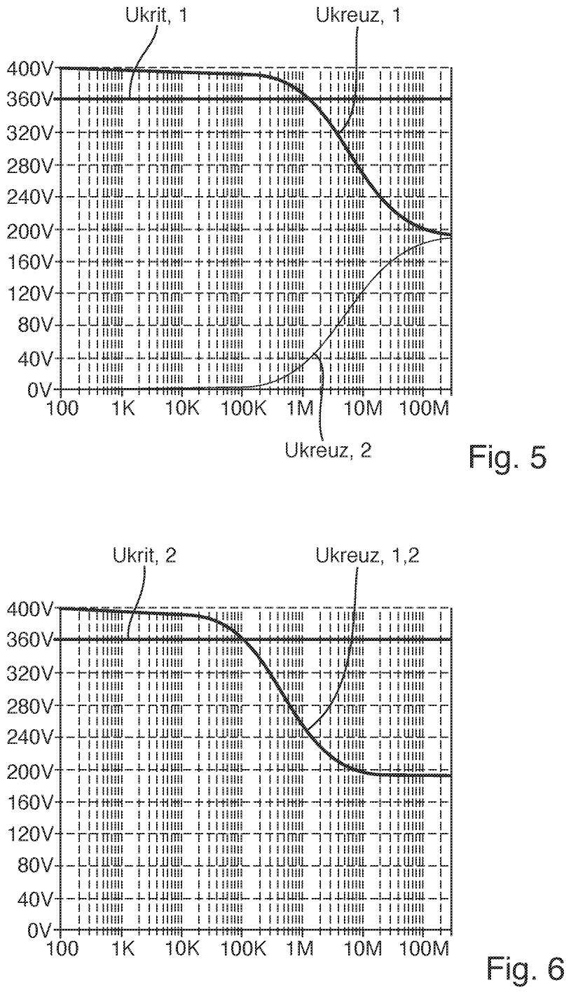

FIG. 5 represents an exemplary simulated voltage characteristic of the crossover voltage plotted against insulation resistance, i.e. against the electrical resistance of the respective open contactor. With respect to FIG. 5, the upper characteristic corresponds to the voltage characteristic of the first crossover voltage Ukreuz, 1 whereas the lower characteristic corresponds to the voltage characteristic of the second crossover voltage Ukreuz, 2. This is exemplary only and an inverse assignment could equally well be applied.

In the example according to FIG. 5, the first contactor 1 is subject to substantial ageing, and the internal resistance thereof declines. In the simulation, it is simultaneously assumed that the second contactor 2 maintains its (high) internal resistance and has thus undergone no visible ageing. This can be inferred from the first crossover voltage Ukreuz, 1, i.e. the upper characteristic. The crossover voltage Ukreuz, 1 thus increases as the insulation resistance of the first contactor 1 declines. In other words, the first contactor 1 is no longer fully capable of isolating the first interface 5 from the voltage which is generated by the battery cell 4 such that, in this case, voltage transfer occurs across the open contactor 1. This is detected by the measurement of the first crossover voltage Ukreuz, 1.

In order to monitor this ageing process of the first contactor 1, a first voltage threshold value Ukrit, 1 is defined. This first voltage threshold value Ukrit, 1 can be inferred, for example, from the simulation of the circuit represented in FIG. 5 wherein the first voltage threshold value Ukrit 1 is then inferred from a (simulated) internal resistance of the contactor 1 which is assumed to be critical. In one example, the first voltage threshold value Ukrit, 1 can be established, for example at a (simulated) internal resistance of 1.4 megaohms. If the crossover voltage Ukreuz, 1 then measured in the circuit exceeds the voltage threshold value Ukrit, 1, it is assumed that the internal resistance of the contactor 1 has fallen below a critical value and therefore the battery pack 3 may no longer be switched on.

In order to define a voltage threshold value which is not stipulated as an absolute value but adapts to the respective state-of-charge of battery cells, a voltage threshold value of 90% of a first reference voltage (in this case 400 V) can also be defined, for example. As soon as the measured or detected first crossover voltage Ukreuz, 1 achieves or exceeds the first voltage threshold value Ukrit, 1, a critical state of health of the first contactor 1 is reached. Consequently, in such a case, closing of the respective contactor can be prevented and a corresponding message can be sent to a battery control device.

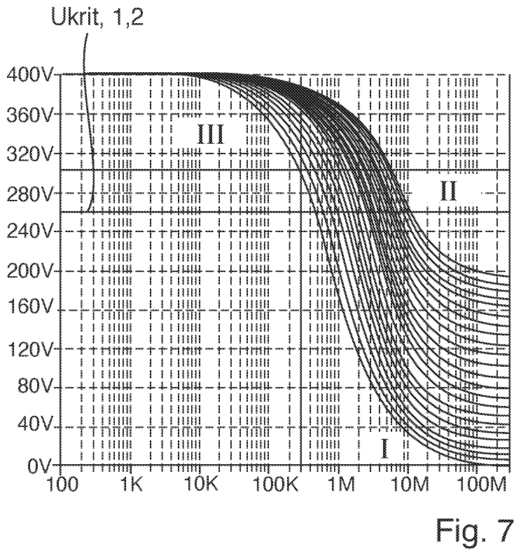

In order to prevent the battery pack from suddenly ceasing to function here without warning because the voltage threshold is exceeded, a warning voltage threshold value can additionally be defined at which a warning message is output to a central battery controller. The warning voltage threshold value is in several embodiments dimensioned such that the battery pack can still be operated for a while before the voltage threshold value is reached and the further use of the battery pack is suppressed. The warning voltage threshold value is in some embodiments set in such a way that, for example, in the case of use of the battery pack in a vehicle, the vehicle driver has sufficient time during regular operation of the vehicle to arrange a service appointment at a workshop and the vehicle can continue to be operated regularly until then. The warning voltage threshold value can be set accordingly, for example, at 80% of the reference voltage or at a calculated internal resistance of the respective contactor derived from the simulation, which is at a warning value. FIG. 6 shows a further simulation of the crossover voltage plotted against insulation resistance. In FIG. 6, the characteristics of the first crossover voltage Ukreuz, 1 and the second crossover voltage Ukreuz, 2 coincide such that only one curve can be recognized. It is assumed here that both the contactors 1, 2 undergo an identical ageing process. Thus, as the insulation resistance decreases, the crossover voltages Ukreuz, 1, 2 increase. Consequently, in the example shown in FIG. 2, closing of the respective contactors 1, 2 is also suppressed when a second voltage threshold value Ucrit, 2 is reached. In FIG. 7, a further diagram is represented in which various simulations of crossover voltages are plotted against insulation resistance. Here, individual areas are highlighted. In the area identified as “I”, i.e. in the area having relatively high resistances and relatively low voltages, the contactor is still able to execute its function reliably. If the insulation resistance decreases further and the voltage increases further, i.e. into area II, serious ageing has already been reached. In this area, a warning is sent to the respective battery controller. If the respective contactor continues to age, i.e. if the resistance as well as the voltage continue to increase, see area III, disconnection of the respective interface line from the interface is no longer guaranteed when the respective contactor is opened, which is why closing is prevented in these areas. This area is also referred to as the fault area, in which closing of the contactor must be prevented for safety reasons. This is efficiently achieved by the proposed method, wherein a measurement of crossover voltages is sufficient to permit a reliable conclusion to be drawn with respect to the state of health of a contactor.

The above-mentioned method can be implemented in a battery control system wherein, in an exemplary configuration, individual steps of execution are set down in the form of machine-executable instructions which can be executed by a processor of the battery control system. Machine-executable instructions can in certain embodiments be saved on a non-volatile computer-readable storage medium, for example in the form of a ROM, an EPROM or a hard disk memory.

To the extent applicable, any of the individual features shown in the embodiments may be combined and/or interchanged without departing from the scope of the invention.

1-12. (canceled)

13. A method for monitoring a state of health of a contactor in a battery pack, comprising:
(i) measuring a first differential voltage across a switchable first contactor in an open position; and
(ii) monitoring a state of health of the switchable first contactor based on the measured first differential voltage, or
(i) measuring a second differential voltage across a switchable second contactor in an open position; and
(ii) determining a state of health of the switchable second contactor based on the measured second differential voltage,
wherein the battery pack comprises:
a battery cell configured to electrochemically store electrical energy;
a first interface line and a second interface line, each interface line configured to deliver electrical energy to an interface;
the switchable first contactor arranged in the first interface line between the interface and the battery cell; and
the switchable second contactor arranged in the second interface line between the interface and the battery cell.

14. The method of claim 13, further comprising delivering information on the state of health of the switchable first contactor or the switchable second contactor to a control device, a display unit, or a user.

15. The method of claim 13, wherein:
monitoring the state of health of the switchable first contactor is based on a comparison of the measured first differential voltage with a first voltage threshold value; or
determining the state of health of the switchable second contactor is based on a comparison of the measured second differential voltage with a second voltage threshold value.

16. The method of claim 15, further comprising setting the first voltage threshold value or the second voltage threshold value.

17. The method of claim 13, further comprising measuring the first differential voltage or the second differential voltage in relation to a reference potential.

18. The method of claim 17, wherein the first differential voltage or the second differential voltage comprises a crossover voltage, and measuring the first differential voltage or the second differential voltage comprises measuring the crossover voltage via a respective switchable contactor in the open position with respect to the reference potential.

19. The method of claim 13, wherein:
(iii) the switchable first contactor is arranged between a first interface node point facing the interface and a first battery cell node point facing the battery cell, and
(iv) the switchable second contactor is arranged between a second interface node point facing the interface and a second battery cell node point facing the battery cell, and
(v) the first differential voltage comprises a first crossover voltage present between the first interface node point and the second battery cell node point, or
(vi) the second differential voltage comprises a second crossover voltage present between the second interface node point and the first battery cell node point.

20. The method of claim 19, further comprising:
suppressing switching of the switchable first contactor when the first crossover voltage or the first differential voltage exceeds a first voltage threshold value; or
suppressing switching of the switchable second contactor when the second crossover voltage or the second differential voltage exceeds a second voltage threshold value.

21. The method of claim 20, further comprising:
generating a warning signal when the first crossover voltage or the first differential voltage exceeds a first warning voltage threshold value; or
generating a warning signal when the second crossover voltage or the second differential voltage exceeds a second warning voltage threshold value.

22. The method of claim 21, further comprising transmitting the warning signal to a control device, a display unit, or a user.

23. The method of claim 21, wherein the first warning voltage threshold value comprises a percentage of a first voltage threshold value, or the second warning voltage threshold value comprises a percentage of a second voltage threshold value.

24. The method of claim 23, further comprising:
determining a first reference voltage between a first battery cell node point of the switchable first contactor and a second battery cell node point of the switchable second contactor; or
determining a second reference voltage between a first interface node point of the switchable first contactor and a second interface node point of the switchable second contactor.

25. The method of claim 24, wherein the first voltage threshold value is determined in accordance with the first reference voltage, or the second voltage threshold value is determined in accordance with the second reference voltage.

26. The method of claim 13, further comprising monitoring the state of health of the switchable first contactor or the switchable second contactor prior to any switching process for closing of the respective contactor.

27. The method of claim 13, further comprising continuously measuring the first differential voltage or the second differential voltage.

28. A battery control system for employment in a battery pack, wherein the battery control system is configured to execute the method of claim 13.

29. A battery pack for a delivery of electrical energy to an electric drive unit, comprising:
a battery cell;
a first interface line and a second interface line, each interface line configured to deliver electrical energy to an interface;
a switchable first contactor arranged in the first interface line between a first interface node point and a first battery cell node point;
a switchable second contactor arranged in the second interface line between a second interface node point and a second battery cell node point; and
the battery control system of claim 28.

30. A non-transitory computer-readable medium having stored thereon computer-readable instructions executable by a processor to perform operations which comprise the method of claim 13.

31. A method for monitoring a state of health of a contactor in a battery pack, comprising:
(i) measuring a first differential voltage across a switchable first contactor in an open position;
(ii) monitoring a state of health of the switchable first contactor based on the measured first differential voltage;
(iii) measuring a second differential voltage across a switchable second contactor in an open position; and
(iv) determining a state of health of the switchable second contactor based on the measured second differential voltage,
wherein the battery pack comprises:
a battery cell configured to electrochemically store electrical energy;
a first interface line and a second interface line, each interface line configured to deliver electrical energy to an interface;
the switchable first contactor arranged in the first interface line between the interface and the battery cell; and
the switchable second contactor arranged in the second interface line between the interface and the battery cell.

32. The method of claim 31, wherein:
monitoring the state of health of the switchable first contactor is based on a comparison of the measured first differential voltage with a first voltage threshold value; or
determining the state of health of the switchable second contactor is based on a comparison of the measured second differential voltage with a second voltage threshold value, wherein the first voltage threshold value and the second voltage threshold value are pre-set.
